(19) United States
(12) Patent Application Publication
(10) Pub. No.: US 2024/0222224 A1
(43) Pub. Date: Jul. 4, 2024

(54) SUBSTRATES OF SEMICONDUCTOR DEVICES FOR HEAT DISSIPATION

(71) Applicant: GlobalFoundries U.S. Inc., MALTA, NY (US)

(72) Inventors: SIVA P. ADUSUMILLI, South Burlington, VT (US); STEVEN SHANK, Jericho, VT (US); RAJENDRAN KRISHNASAMY, Burlington, VT (US); YVES NGU, Burlington, VT (US)

(21) Appl. No.: 18/148,404

(22) Filed: Dec. 29, 2022

(51) Int. Cl. H01L 23/46; H01L 21/20; H01L 21/768; H01L 23/13

(52) U.S. Cl. CPC H01L 23/46; H01L 21/20; H01L 21/76882; H01L 23/13

(57) ABSTRACT

A semiconductor structure is provided. The semiconductor structure includes a substrate, a channel, and a semiconductor device. The channel is in the substrate for a fluid to flow through and includes a first channel portion having a first volume, a second channel portion having a second volume, and a third channel portion connecting the first channel portion to the second channel portion. The third channel portion has a third volume smaller than the first volume and the second volume. The semiconductor device is vertically over the channel.

### TECHNICAL FIELD

The present disclosure relates generally to semiconductor devices, and more particularly to substrates of semiconductor devices having a channel for heat dissipation and methods of forming the same.

### BACKGROUND

A semiconductor device may generate heat during operation. Heat may degrade the electrical performance of the semiconductor device and cause reliability issues. For example, when the temperature of a semiconductor device, such as a transistor, exceeds a threshold temperature, there is a reduction in carrier mobility. At the extreme end, heat can damage the semiconductor device and shorten the average lifespan thereof.

As technology advances with a continuing demand for greater integration of semiconductor devices to provide a multitude of functions, the issues associated with heat may be exacerbated. Therefore, solutions are provided to overcome, or at least ameliorate, the disadvantages described above.

### SUMMARY

To achieve the foregoing and other aspects of the present disclosure, substrates of semiconductor devices having a channel for heat dissipation and methods of forming the same are presented.

According to an aspect of the present disclosure, a semiconductor structure is provided. The semiconductor structure includes a substrate, a channel, and a semiconductor device. The channel is in the substrate for a fluid to flow through and includes a first channel portion having a first volume, a second channel portion having a second volume, and a third channel portion connecting the first channel portion to the second channel portion. The third channel portion has a third volume smaller than the first volume and the second volume. The semiconductor device is vertically over the channel.

According to another aspect of the present disclosure, a semiconductor structure is provided. The semiconductor structure includes a substrate, a channel, a semiconductor device, and a dielectric layer. The substrate includes a base layer having an upper base surface and a device layer over the base layer. The channel is in the base layer for a fluid to flow through and includes a first channel portion at a first depth from the upper base surface, a second channel portion at a second depth from the upper base surface, and a third channel portion connecting the first channel portion to the second channel portion. The third channel portion is at a third depth from the upper base surface and the third depth is shallower than the first depth and the second depth. The semiconductor device is vertically over the channel. The dielectric layer is over the substrate and covers the semiconductor device.

According to yet another aspect of the present disclosure, a method of forming a semiconductor structure is provided. The method includes forming a channel in a base layer for a fluid to flow through and forming a device layer of the base layer. The base layer has an upper base surface. The channel includes a first channel portion having a first volume, a second channel portion having a second volume, and a third channel portion connecting the first channel portion to the second channel portion. The third channel portion has a third volume smaller than the first volume and the second volume. A semiconductor device is formed vertically over the channel. A first opening and a second opening are formed through the device layer to connect to the channel. The first opening and a second opening are formed at laterally opposite sides of the semiconductor device.

### BRIEF DESCRIPTION OF THE DRAWINGS

The embodiments of the present disclosure will be better understood from a reading of the following detailed description, taken in conjunction with the accompanying drawings:

FIG. 1A is a top-down view of a substrate of a semiconductor structure and FIGS. 1B to 1C are cross-sectional views (taken generally along line A-A′ and line B-B′, respectively, in FIG. 1A) of the semiconductor structure, according to an embodiment of the disclosure.

FIG. 2A is a top-down view of a substrate of a semiconductor structure and FIG. 2B is a cross-sectional view (taken generally along line B-B′ in FIG. 2A) of the semiconductor structure, according to another embodiment of the disclosure.

FIG. 3 is a cross-sectional view of a semiconductor structure, according to yet another embodiment of the disclosure.

FIG. 4 is a cross-sectional view of a semiconductor structure, according to a further embodiment of the disclosure.

FIGS. 5A through 5G are cross-sectional views of the semiconductor structure, illustrating a method of forming a channel in a substrate for heat dissipation, according to an embodiment of the disclosure.

FIG. 6 is a cross-sectional view of a semiconductor structure at a fabrication stage subsequent to FIG. 5D, according to another embodiment of the disclosure.

For simplicity and clarity of illustration, the drawings illustrate the general manner of construction, and certain descriptions and details of well-known features and techniques may be omitted to avoid unnecessarily obscuring the discussion of the described embodiments of the disclosure.

Additionally, features in the drawings are not necessarily drawn to scale. For example, the dimensions of some of the features in the drawings may be exaggerated relative to other features to help improve the understanding of embodiments of the device. The same reference numerals in different drawings denote the same features, while similar reference numerals may, but do not necessarily, denote similar features.

### DETAILED DESCRIPTION

The present disclosure relates to substrates of semiconductor devices having a channel for heat dissipation and methods of forming the same. Various embodiments of the present disclosure are now described in detail with accompanying drawings. It is noted that like and corresponding features are referred to by the use of the same reference numerals. The embodiments disclosed herein are exemplary, and not intended to be exhaustive or limiting to the disclosure.

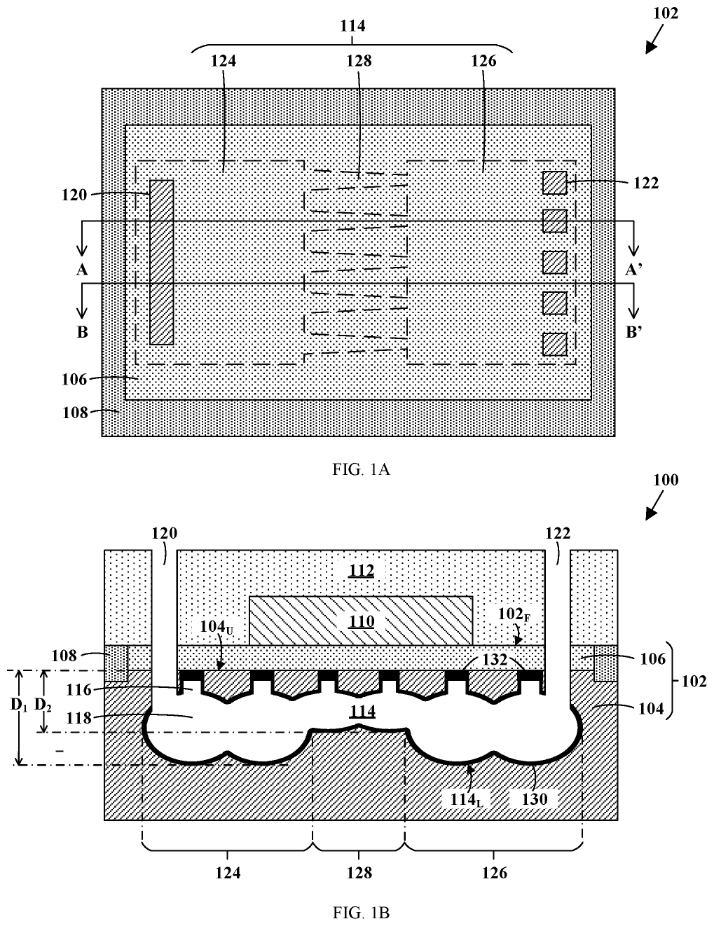

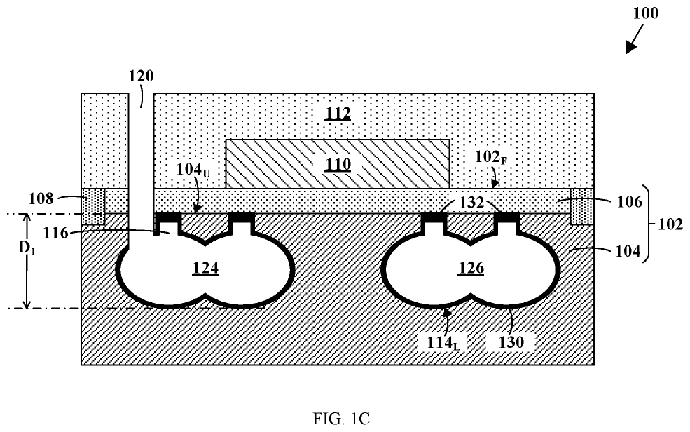

FIG. 1A is a top-down view of a substrate 102 of a semiconductor structure 100 and FIGS. 1B to 1C are cross-sectional views (taken generally along line A-A′ and line B-B′, respectively, in FIG. 1A) of the semiconductor structure 100, according to an embodiment of the disclosure. The substrate 102 has a front substrate surface 102_{F} and may include a base layer 104 and a device layer 106 over the base layer 104. The base layer 104 may include a semiconductor material, for example, silicon, silicon germanium, silicon carbide, or other II-VI or III-V semiconductor compounds, and has an upper base surface 104_{U}.

The device layer 106 may be in contact with the upper base surface 104_{U}. The device layer 106 may also be referred to as an active layer. The device layer 106 may be where semiconductor components, for example, active devices and/or passive devices, may be arranged adjacent to, in, and/or above the substrate 102. The device layer 106 has an upper surface that may be synonymous with the front substrate surface 102_{F} of the substrate 102. The device layer 106 may include a semiconductor material, for example, silicon, silicon germanium, gallium nitride, or other II-VI or III-V semiconductor compounds. The semiconductor material of the device layer 106 may be doped or undoped. In an embodiment of the disclosure, the semiconductor material of the device layer 106 may include the same semiconductor material as the base layer 104. In another embodiment of the disclosure, the semiconductor material of the device layer 106 may include a different semiconductor material than the base layer 104.

The semiconductor structure 100 may also include an isolation structure 108 in the substrate 102. The isolation structure 108 may demarcate an area of the device layer 106 and electrically isolate the demarcated area from adjacent electrically conductive features, for example, another semiconductor structure sharing the same device layer 106. The isolation structure 108 may extend downwardly from the front substrate surface 102_{F} and at least extend through the device layer 106. For example, the isolation structure 108 may terminate within the base layer 104 of the substrate 102, as illustrated in FIG. 1B. In another example, the isolation structure 108 may terminate on the upper base surface 104_{U}. The isolation structure 108 may include an electrically insulative material, for example, silicon oxide, silicon nitride, silicon oxynitride, or a combination thereof.

The semiconductor structure 100 may further include a semiconductor device 110 within the boundary of the isolation structure 108. The semiconductor device 110 may include an active component, for example, a transistor or a diode, or a passive component, for example, an inductor or a resistor. The semiconductor device 110 may be predominantly over the device layer 106 of the substrate 102. For example, in embodiments where the semiconductor device 110 is a transistor, conductive wells and diffusion regions may be in the device layer 106, while gate structures and interconnect structures may be above the device layer 106. In another example, in embodiments where the semiconductor device 110 is a resistor, the semiconductor device 110 may be over the device layer 106 of the substrate 102. A dielectric layer 112 may be arranged over the substrate 102, covering at least the semiconductor device 110.

The substrate 102 may include a channel 114 within the base layer 104 of the substrate 102 and vertically under the semiconductor device 110; the outline of the channel 114 is demarcated by a dashed line for purposes of illustration in FIG. 1A. The channel 114 may contribute to heat dissipation of the semiconductor structure 100, and may be surrounded by the base layer 104 from below and laterally. For example, portions of the base layer 104 may enclose the channel 114 and define longitudinal and transverse boundaries thereof. The longitudinal boundary of the channel 114 may be referred to as the length thereof and the transverse boundary may be referred to as the width thereof. The channel 114 may include trenches 116 that are spaced apart by a portion of the base layer 104 therebetween and a cavity 118 under the trenches 116, spatially connecting thereto. In an embodiment of the disclosure, the channel 114 has a lower surface 114L that may be undulated.

The channel 114 may extend beyond the boundaries of the semiconductor device 110 and the semiconductor device 110 may be arranged entirely over the channel 114. Openings 120 and 122 may be arranged to spatially connect to the channel 114. For example, the openings 120 and 122 may be arranged at, or proximate to, the laterally opposite ends of the channel 114, and the channel 114 is an unsealed, or open, channel in the base layer 104 of the substrate 102. The semiconductor device 110 may be arranged laterally between the openings 120 and 122. The openings 120 and 122 may be arranged partially through the substrate 102 and at least extending through the device layer 106 and a portion of the base layer 104 to the channel 114. The openings 120 and 122 may further extend through the dielectric layer 112.

The channel 114 may enable fluids to flow through along the length thereof and may be referred to as a fluidic channel. The term “fluids” as used herein may include a substance, such as a liquid or gas, tending to flow or conform to the outline of its container, for example, the channel 114. The openings 120 and 122 may serve as either an inlet or an outlet of the channel 114 where a fluid enters and exits the channel 114, respectively. The openings 120 and 122 may include a line opening, i.e., a trench, and/or a via opening, i.e., a hole, and the opening 120 need not necessarily have the same form as the opening 122. For example, the opening 120 is illustrated as a line opening while the opening 122 is illustrated as a via opening in FIG. 1A. In instances where either the opening 120 or the opening 122 is a via opening, it may be preferable to have a plurality of via openings for efficient inflow and/or outflow of the fluid to and from the channel 114, respectively. For example, FIG. 1A illustrates five via openings 122, although the number of via openings may vary according to the design requirements of the semiconductor structure 100.

The openings 120 and 122 may not necessarily have the same width dimension as each other, even though FIGS. 1A and 1B illustrate the openings 120 and 122 as such. For example, the opening 120 may be wider or narrower than the opening 122. As used herein, the width dimension of the openings 120 and 122 is defined as a dimension parallel to the length of the channel 114. In an embodiment of the disclosure, the openings 120 and 122 may each have a substantially constant width dimension.

The channel 114 may vary volumetrically along the length thereof, for example, between the openings 120 and 122. The channel 114 may include a chamber 124 having a first volume, a chamber 126 having a second volume, and at least one passage 128 connecting to, and merges with, the chamber 124 and the chamber 126. Portions of the base layer 104 may define the longitudinal boundary of the passage 128 which is along the longitudinal boundary of the channel 114. In this embodiment, FIG. 1A illustrates five passages 128, and each passage 128 may be separated from an adjacent passage 128 by a portion of the base layer 104, as illustrated in FIG. 1C. The portion of the base layer 104 may be surrounded by the chamber 124, the chamber 126, and the adjacent passages 128, contributing to the heat dissipation of the semiconductor structure 100.

Although FIG. 1A only illustrates five passages 128, the number of passages 128 may vary according to the design requirements of the semiconductor structure 100. Additionally, even though the chamber 124 and the chamber 126 are illustrated to be spatially or volumetrically similar to each other in FIGS. 1A to 1C, the chamber 124 may have a different volume from the chamber 126.

The passage 128 is volumetrically smaller than the chamber 124 and the chamber 126, and the passage 128 may provide a constricted pathway therebetween. For example, the cross-sectional area of the chamber 124 and the cross-sectional area of the chamber 126, taken perpendicular to the length of the channel 114, may be larger than the cross-sectional area of the passage 128. Accordingly, the passage 128 may be able to regulate the flow rate of the fluid through the channel 114 from the chamber 124 to the chamber 126, or vice versa. For example, the fluid may flow through the passage 128 at a higher flow rate, i.e., faster, than the chamber 124 or the chamber 126 as the cross-sectional area of the passage 128 is smaller than that of the chamber 124 and the chamber 126.

The channel 114 may have varying depths relative to the upper base surface 104_{U}. For example, the chamber 124 and the chamber 126 may extend to a deeper depth within the base layer 104 than the passage 128. In another example, the chamber 124 may extend to a maximum depth D₁ from the upper base surface 104_{U} and the passage 128 may extend to a maximum depth D₂ from the upper base surface 104_{U}, and the depth D₁ is deeper than D₂. In an embodiment of the disclosure, the depth D₂ may be about 0.25 to about 0.75 of the depth D₁.

The passage 128 may adopt various geometric configurations. In an embodiment of the disclosure, the cross-sectional area of the passage 128 may vary with position along the length of the channel 114, as illustrated in FIG. 1A. For example, the passage 128 may have a maximum cross-sectional area occurring at one end and the passage 128 may be tapered in a direction towards an opposite end having a minimum cross-sectional area. In this embodiment, the opening 120 may be preferably an inlet where the fluid can flow into the channel 114 and the opening 122 may be preferably an outlet where the fluid can flow out of the channel 114 to advantageously minimize the occurrences of fluid backflow to the inlet, i.e., the opening 120. Alternatively, the passage 128 may have a substantially constant cross-sectional area along the channel 114. In this embodiment, the opening 120 may be an inlet and the opening 122 may be an outlet, or vice versa.

The channel 114 may include a liner 130 along the surfaces thereof. The liner 130 may be conformal and continuous, lining the surfaces of the chamber 124, the chamber 126, and the passage 128, including surfaces of the trenches 116 and the cavity 118. The liner 130 may include a semiconductor material, for example, silicon germanium.

The semiconductor device 110 may further include plugs 132 in the base layer 104 of the substrate 102. The plugs 132 may plug, or fill, at least the upper portions of the trenches 116. The plugs 132 may be in direct contact with the device layer 106. In an embodiment of the disclosure, the plugs 132 may include the same material as the liner 130, for example, silicon germanium or germanium.

A fluid may be guided through the channel 114, absorbing or extracting heat that may be generated by the semiconductor device 110, and removing the heat from the semiconductor structure 100 when the fluid leaves the channel 114. The fluid may include a heat-absorbing fluid, for example, a coolant or a heat-transfer fluid. Preferably, the fluid may have a high thermal capacity to extract heat from the semiconductor device 110 effectively and efficiently. The fluid may also be preferably electrically insulative and has a sufficiently low dielectric constant to not interfere with the electrical operations of the semiconductor device 110. In an embodiment of the disclosure, the fluid may include a liquid, for example, liquid nitrogen or water. In another embodiment of the disclosure, the fluid may include a gas, for example, air or hydrogen.

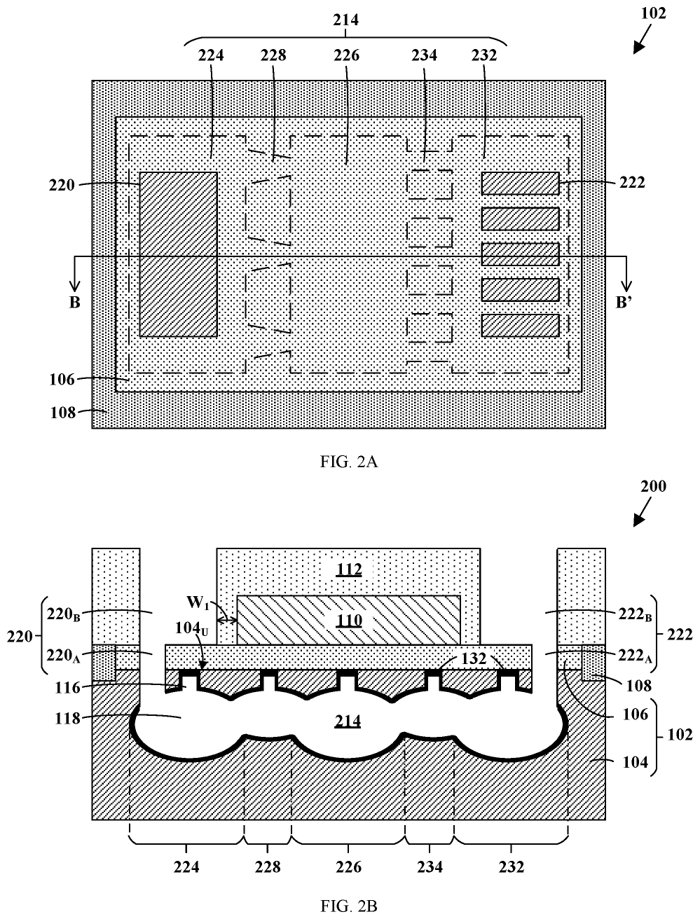

FIG. 2A is a top-down view of a substrate 102 of a semiconductor structure 200 and FIG. 2B is a cross-sectional view (taken generally along line B-B′ in FIG. 2A) of the semiconductor structure 200, according to an embodiment of the disclosure. The semiconductor structure 200 may be similar to the semiconductor structure 100, and thus common features are labeled with the same reference numerals and need not be discussed.

Similar to the semiconductor structure 100, the semiconductor structure 200 may also include a channel 214 within the base layer 104 of the substrate 102 vertically under the semiconductor device 110; the outline of the channel 214 is demarcated by a dashed line for purposes of illustration in FIG. 2A. The channel 214 may vary volumetrically along the length thereof. The channel 214 may include a chamber 224, a chamber 226, and a chamber 232. The chamber 224, the chamber 226, and the chamber 232 may or may not be spatially or volumetrically similar to each other.

The channel 214 may further include at least one passage 228 between the chamber 224 and the chamber 226, and at least one passage 234 between the chamber 226 and the chamber 232. The number of passages 228 and 234 may vary according to the design requirements of the semiconductor structure 200. Each of the passages 228 and 234 may be volumetrically smaller than either the chamber 224, the chamber 226, or the chamber 232. The passages 228 and 234 may provide a constricted pathway to regulate the flow rate of a fluid when guided through the channel 214.

The passages 228 and 234 may adopt geometric configurations that are similar to or different from each other. For example, the passage 228 may have a cross-sectional area that varies with position, and the passage 234 may have a substantially constant cross-sectional area along the channel 114, as illustrated in FIG. 2A. Alternatively, the passage 228 may have a substantially constant cross-sectional area and the passage 234 may have a cross-sectional area that varies with position along the channel 114. In other embodiments of the disclosure, the passages 228 and 234 may include cross-sectional areas that vary along the channel 114, or the passages 228 and 234 may have substantially constant cross-sectional areas.

Openings 220 and 222 may be arranged to spatially connect to the channel 214. For example, the openings 220 and 222 may be arranged at, or proximate to, the laterally opposite ends of the channel 214, and the channel 214 is an unsealed, or open, channel in the base layer 104 of the substrate 102. The openings 220 and 222 may be arranged partially through the substrate 102. For example, the opening 220 may have a first opening portion 220_{A} extending through the device layer 106 and a portion of the base layer 104 to connect to, or merge with, the channel 214. The opening 220 may further include a second opening portion 220_{B} over the first opening portion 220_{A}. The second opening portion 220_{B} may extend through the dielectric layer 112. The second opening portion 220_{B} may have a wider width than the first opening portion 220_{A}.

Similarly, the opening 222 may have a first opening portion 222_{A} and a second opening portion 222_{B} over the first opening portion 222_{A}. The first opening portion 222_{A} may extend through the device layer 106 and a portion of the base layer 104 to connect to, or merge with, the channel 214, and the second opening portion 222; may extend through the dielectric layer 112.

The openings 220 and 222 may include a line opening, i.e., a trench, and/or a via opening, i.e., a hole, and the opening 220 need not necessarily have the same form as the opening 222. The number and geometric configurations of the openings 220 and 220 may vary according to the design requirements of the semiconductor structure 200.

Due to the openings 220 and 222, the channel 214 may be an unsealed, or open, channel enabling a fluid to flow in and out of the channel 214. The second opening portions 220_{B} and 222_{B} may enable the fluid to be laterally closer to the semiconductor device 110, enabling more efficient lateral heat extraction therefrom. In an embodiment of the disclosure, the portion of the dielectric layer 112 between the second opening portion 220_{B} and the semiconductor device 110 may have a width W₁ of at least 10 nanometers (nm).

FIG. 3 is a cross-sectional view of a semiconductor structure 300, according to another embodiment of the disclosure. The semiconductor structure 300 may be similar to the semiconductor structure 100, and thus common features are labeled with the same reference numerals and need not be discussed.

The semiconductor structure 300 may include a plurality of semiconductor devices 110 over the channel 114. The openings 120 and 122 to the channel 114, serving as an inlet or an outlet, may be arranged in the isolation structure 108 surrounding each semiconductor device 110, and the plurality of semiconductor devices 110 may be arranged within the boundary of the channel 114. The plurality of semiconductor devices 110 may include active components and/or passive components.

FIG. 4 is a cross-sectional view of a semiconductor structure 400, according to another embodiment of the disclosure. The semiconductor structure 400 may be similar to the semiconductor structure 300, and thus common features are labeled with the same reference numerals and need not be discussed.

Similar to the semiconductor structure 300, the semiconductor structure 400 may also include a semiconductor device 110 over the channel 114. The semiconductor structure 400 may further include non-functional, or dummy, semiconductor devices 410. Openings 434 and 436 may be arranged through the non-functional semiconductor devices 410 to connect to, or merge with, the channel 114. The openings 434 and 436 may serve as an inlet or outlet of the channel 114.

As illustrated in FIG. 4, the openings 434 and 436 may be additional openings to the openings 120 and 122, even though not necessarily so. The opening 434 is arranged proximate to the opening 120, and the opening 434 may allow the fluid to flow in the same direction as the fluid flowing through the opening 120. Similarly, the opening 436 is arranged proximate to the opening 122, and the opening 436 may allow the fluid to flow in the same direction as the fluid flowing through the opening 122.

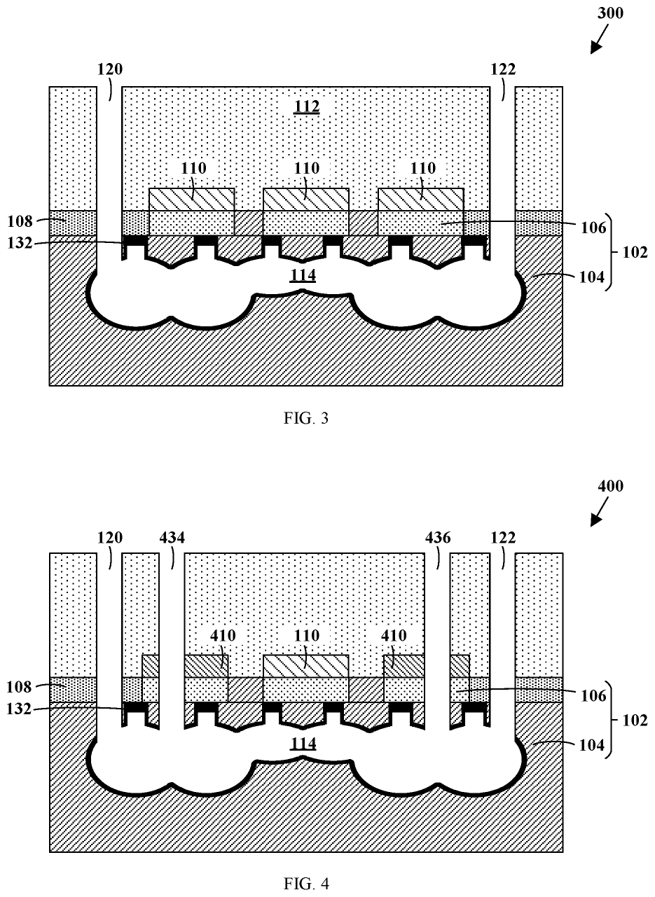

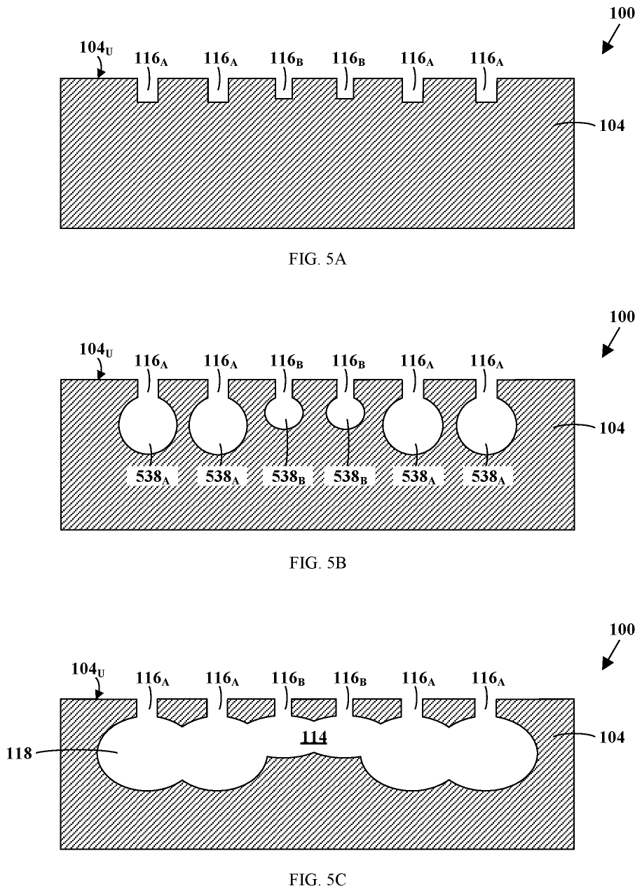

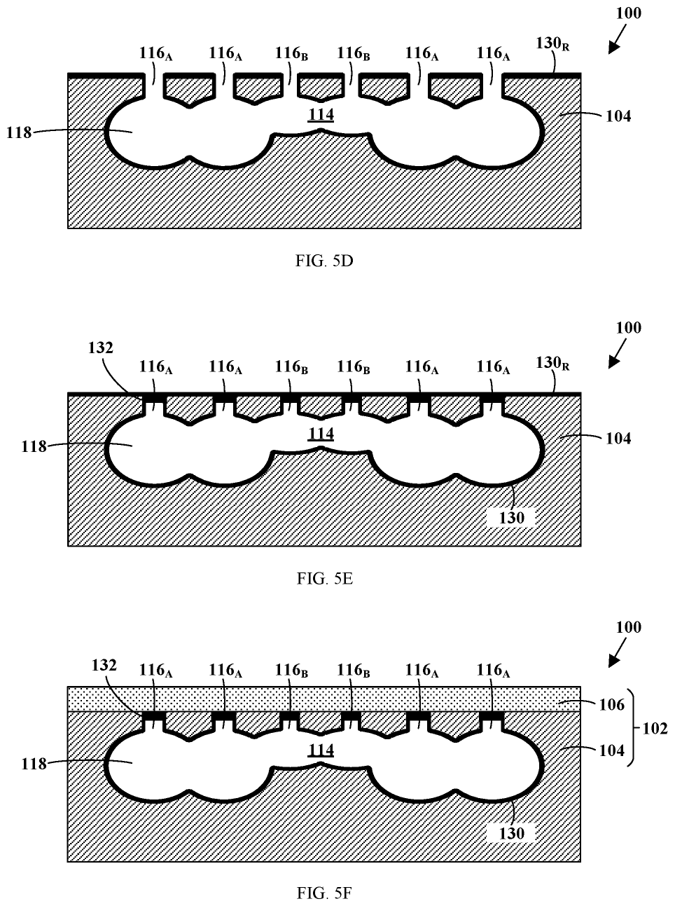

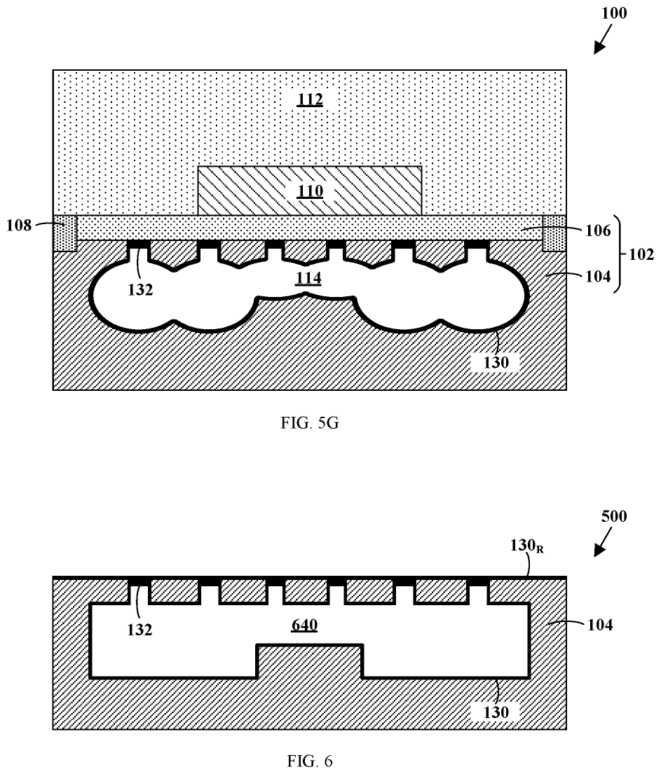

FIGS. 5A through 5G are cross-sectional views of the semiconductor structure 100, illustrating a method of forming the channel 114 in the substrate 102 for heat dissipation, according to an embodiment of the disclosure. Certain structures may be conventionally fabricated, for example, using known processes and techniques, and specifically disclosed processes and methods may be used to achieve individual aspects of the present disclosure.

FIG. 5A is a cross-sectional view of the semiconductor structure 100 at an initial fabrication stage of a processing method, according to an embodiment of the disclosure. The semiconductor structure 100 may include a base layer 104 serving as a precursor upon which a device layer 106 may be formed thereupon in subsequent processing steps. The base layer 104 may include a semiconductor material, for example, silicon, silicon germanium, silicon carbide, or other II-VI or III-V semiconductor compounds.

Trenches 116_{A} and 116_{B} may be formed in the base layer 104, extending downwardly from the upper base surface 104_{U}. The trenches 116_{A} and 116_{B} may include line openings and/or holes. The trenches 116_{A} and 116_{B} may have substantially straight sidewalls and may include different width dimensions, for example, the trenches 116_{B} may be narrower than the trenches 116_{A}. The trenches 116_{A} and 116_{B} may be formed by a patterning technique, including lithography and etching processes.

FIG. 5B is a cross-sectional view of the semiconductor structure 100 at a fabrication stage subsequent to FIG. 5A, according to an embodiment of the disclosure. Cavities 538_{A} and 538_{B} may be formed in the base layer 104 through the bottom of the trenches 116_{A} and 116_{B}, respectively. The cavities 538_{A} and 538_{B} may be formed by a material removal technique, including an anisotropic etching process, to remove portions of the base layer 104 through the trenches 116_{A} and 116_{B}. The cavities 538_{A} and 538_{B} may have curved surfaces.

A protective liner (not shown) may be deposited on at least the sidewalls of the trenches 116_{A} and 116_{B} to protect the sidewalls from being unintentionally removed during the formation of the cavities 538_{A} and 538_{B}. The bottom surfaces of the trenches 116_{A} and 116_{B} may be exposed for the formation of the cavities 538_{A} and 538_{B} in the base layer 104. In an embodiment of the disclosure, the protective liner may include a dielectric material, for example, silicon oxide, silicon nitride, or a combination of silicon oxide and silicon nitride.

The cavities 538_{A} and 538_{B} may have different spatial dimensions. For example, the cavities 538_{A} under the trenches 116_{A} may have a larger volume than the cavities 538_{B} under the trenches 116_{B}. The difference in spatial dimensions may be due to a micro-loading effect of the material removal technique, where fewer chemicals, for example, etchants, may reach the bottom of the narrower trenches 116_{B} and cause the etch rate to decrease.

FIG. 5C is a cross-sectional view of the semiconductor structure 100 at a fabrication stage subsequent to FIG. 5B, according to an embodiment of the disclosure. The material removal technique may further extend the cavities 538_{A} and 538_{B} laterally and deeper into the base layer 104 until the cavities 538_{A} and 538_{B} merge, or spatially connect, to form a cavity 118 under and spatially connect to the trenches 116_{A} and 116_{B}. The cavity 118, in combination with the trenches 116_{A} and 116_{B}, forms the channel 114 of the semiconductor structure 100. The surfaces of the channel 114 may be undulated, formed from the merging of the cavities 538_{A} and 538_{B}. The protective liner on at least the sidewalls of the openings may be subsequently removed after forming the channel 114.

FIG. 5D is a cross-sectional view of the semiconductor structure 100 at a fabrication stage subsequent to FIG. 5C, according to an embodiment of the disclosure. A reflowable material 130_{R} may be formed over the base layer 104 using a deposition technique, including a chemical-vapor deposition (CVD) process or an epitaxy process. The reflowable material 130_{R} may be continuous and conformally line the surfaces of the channel 114. The reflowable material 130_{R} may include a semiconductor material, for example, silicon germanium. The reflowable material 130_{R} may be deposited to a sufficient thickness to at least plug, or fill, the trenches 116_{A} and 116_{B} during the subsequent process step.

FIG. 5E is a cross-sectional view of the semiconductor structure 100 at a fabrication stage subsequent to FIG. 5D, according to an embodiment of the disclosure. The semiconductor structure 100 may be subjected to a heat treatment to increase the temperature of the reflowable material 130_{R} to at least the reflow temperature thereof so that the reflowable material 130_{R} may reflow, gravitate, or migrate into the trenches 116_{A} and 116_{B} to form plugs 132. The plugs 132 may seal the channel 114, and the reflowable material 130_{R} lining the surfaces of the channel 114 forms a liner 130. The reflowable material 130_{R} may or may not entirely fill the trenches 116_{A} and 116_{B}. As illustrated, the reflowable material 130_{R} may only fill the upper portions of the trenches 116_{A} and 116_{B}. The reflowable material 130_{R} over the base layer 104 may be thinner than the deposited thickness after forming the plugs 132.

FIG. 5F is a cross-sectional view of the semiconductor structure 100 at a fabrication stage subsequent to FIG. 5E, according to an embodiment of the disclosure. The reflowable material 130_{R} over the base layer 104 may be optionally removed using a material removal technique, for example, a chemical mechanical planarization (CMP) process.

A device layer 106 may be formed over the base layer 104 (or the reflowable material 130_{R}) using a deposition technique, for example, an epitaxy process. The device layer 106 may be in direct contact with the base layer 104 and the plugs 132. The base layer 104 (or the reflowable material 130_{R}) may serve as a growth surface during the epitaxy process to grow the device layer 106. A doping technique, including an implantation process or an in-situ doping process, may be optionally performed to dope the device layer 106 with dopants. The device layer 106 may include a semiconductor material, for example, silicon, silicon germanium, gallium nitride, or other II-VI or III-V semiconductor compounds. The device layer 106, in combination with the base layer 104, forms a substrate 102 for the semiconductor structure 100.

FIG. 5G is a cross-sectional view of the semiconductor structure 100 at a fabrication stage subsequent to FIG. 5F, according to an embodiment of the disclosure. The semiconductor structure 100 may undergo further processing steps to form a plurality of features, including an isolation structure 108 in at least the device layer 106, a semiconductor device 110 predominantly over the device layer 106, and a dielectric layer 112 over the substrate 102 covering at least the semiconductor device 110.

Openings 120 and 122, as illustrated in FIG. 1B, may be formed extending through the dielectric layer 112 and the device layer 106, spatially connecting with the channel 114 in the base layer 104. The openings 120 and 122 may serve as an inlet or an outlet of the channel 114 where a fluid enter and exit the channel 114, respectively. Accordingly, the channel 114 is an unsealed, or open, channel in the base layer 104 of the substrate 102. A heat sink (not shown) may be provided outside of the semiconductor structure 100 as a source of the fluid entering the semiconductor structure 100 and as a collection point for the fluid leaving the semiconductor structure 100.

FIG. 6 is a cross-sectional view of a semiconductor structure 500 at a fabrication stage subsequent to FIG. 5D, according to another embodiment of the disclosure. The semiconductor structure 500 may include a channel 640. The channel 640 may be similar to the channel 114, except that the channel 640 may have a substantially smooth and flat surface. During the heat treatment to increase the temperature of the reflowable material 130_{R} as described in FIG. 5E, the temperature could be high enough to cause the cavity 118 to reflow in a planar fashion, resulting the channel 640 acquiring a substantially smooth and flat surface.

The terms “top”, “bottom”, “over”, “under”, and the like in the description and the claims, if any, are used for descriptive purposes and not necessarily for describing permanent relative positions. It is to be understood that the terms so used are interchangeable under appropriate circumstances such that the embodiments of the devices described herein are, for example, capable of operation in other orientations than those illustrated or otherwise described herein.

Additionally, the formation of a first feature over or on a second feature in the description that follows may include embodiments in which the first and second features are formed in direct contact, and may also include embodiments in which additional features may be formed interposing the first and second features, such that the first and second features may not be in direct contact.

Similarly, if a method is described herein as involving a series of steps, the order of such steps as presented herein is not necessarily the only order in which such steps may be performed, and certain of the stated steps may possibly be omitted and/or certain other steps not described herein may possibly be added to the method. Furthermore, the terms “comprise”, “include”, “have”, and any variations thereof, are intended to cover a non-exclusive inclusion, such that a process, method, article, or device that comprises a list of features is not necessarily limited to those features but may include other features not expressly listed or inherent to such process, method, article, or device. Occurrences of the phrase “in an embodiment” herein do not necessarily all refer to the same embodiment.

In addition, unless otherwise indicated, all numbers expressing quantities, ratios, and numerical properties of materials, reaction conditions, and so forth used in the specification and claims are to be understood as being modified in all instances by the term “about”.

Furthermore, approximating language, as used herein throughout the specification and claims, may be applied to modify any quantitative representation that could permissibly vary without resulting in a change in the basic function to which it is related. Accordingly, a value modified by a term or terms, such as “approximately”, “about,”, or “substantially” is not limited to the precise value specified. In some instances, the approximating language may correspond to the precision of an instrument for measuring the value. In other instances, the approximating language may correspond to within normal tolerances of the semiconductor industry. For example, “substantially coplanar” means substantially in a same plane within normal tolerances of the semiconductor industry, and “substantially perpendicular” means at an angle of 90 degrees plus or minus a normal tolerance of the semiconductor industry.

While several exemplary embodiments have been presented in the above-detailed description of the device, it should be appreciated that a number of variations exist. It should further be appreciated that the embodiments are only examples, and are not intended to limit the scope, applicability, dimensions, or configuration of the device in any way. Rather, the above-detailed description will provide those skilled in the art with a convenient road map for implementing an exemplary embodiment of the device, it being understood that various changes may be made in the function and arrangement of features and methods of fabrication described in an exemplary embodiment without departing from the scope of this disclosure as set forth in the appended claims.

What is claimed is:

1. A semiconductor structure, comprising:
a substrate having a front substrate surface;
a channel in the substrate for a fluid to flow through, the channel comprises:
a first channel portion having a first volume;
a second channel portion having a second volume; and
a third channel portion connecting the first channel portion to the second channel portion, the third channel portion having a third volume smaller than the first volume and the second volume; and
a semiconductor device vertically over the channel.

2. The semiconductor structure of claim 1, further comprising:
a first opening partially through the substrate, the first opening connecting to the channel at a first end thereof; and
a second opening partially through the substrate, the second opening connecting to the channel at a second end thereof, the second end is laterally opposite the first end.

3. The semiconductor structure of claim 2, wherein the third channel portion comprises:
a first end having a maximum cross-sectional area connecting to the first channel portion, the first end is proximate to the first opening of the channel; and
a second end having a minimum cross-sectional area connecting to the second channel portion, the second end is proximate to the second opening of the channel.

4. The semiconductor structure of claim 3, wherein the first opening of the channel is an inlet to allow the fluid to flow into the channel and the second opening is an outlet to allow the fluid to leave the channel.

5. The semiconductor structure of claim 2, wherein the first opening comprising:
a first opening portion connecting to the channel, the first opening portion having a first width; and
a second opening portion over the first opening portion, the second opening portion having a second width wider than the first width.

6. The semiconductor structure of claim 5, wherein the first opening portion is in the substrate and the second opening is over the substrate.

7. The semiconductor structure of claim 1, wherein the substrate further comprising:
a base layer within which the channel is arranged therein; and
a device layer over the channel and in contact with the base layer.

8. The semiconductor structure of claim 7, wherein the channel comprises:
trenches spaced apart by a portion of the base layer; and
a cavity under the trenches and connecting thereto.

9. The semiconductor structure of claim 8, further comprising plugs in the trenches and the plugs are in contact with the device layer.

10. The semiconductor structure of claim 9, further comprising a liner in the cavity, the liner comprising the same material as the plugs.

11. The semiconductor structure of claim 10, wherein the material is a semiconductor material.

12. A semiconductor structure, comprising:
a substrate, the substrate comprising:
a base layer, the base layer having an upper base surface; and
a device layer over the base layer;
a channel in the base layer for a fluid to flow through, the channel comprising:
a first channel portion at a first depth from the upper base surface;
a second channel portion at a second depth from the upper base surface; and
a first third channel portion connecting the first channel portion to the second channel portion, the first third channel portion is at a third depth from the upper base surface and the third depth is shallower than the first depth and the second depth;
a semiconductor device vertically over the channel; and
a dielectric layer over the substrate, covering the semiconductor device.

13. The semiconductor structure of claim 12, further comprising:
a first opening through the dielectric layer and partially in the substrate, the first opening connecting to the channel at a first end thereof; and
a second opening through the dielectric layer and partially in the substrate, the second opening connecting to the channel at a second end thereof, the second end is laterally opposite the first end, and the semiconductor device is between the first opening and the second opening.

14. The semiconductor structure of claim 13, further comprising:
a non-functional semiconductor device over the channel and adjacent to the semiconductor device; and
a third opening through the non-functional semiconductor device connecting to the channel.

15. The semiconductor structure of claim 12, further comprising:
a fourth channel portion; and
a fifth channel portion connecting the second channel portion to the fourth channel portion, and the fifth channel portion is at a shallower depth than the fourth channel portion from the upper base surface.

16. A method of forming a semiconductor structure, comprising:
forming a channel in a base layer for a fluid to flow through, the base layer has an upper base surface, and the channel comprises:
a first channel portion having a first volume;
a second channel portion having a second volume; and
a third channel portion connecting the first channel portion to the second channel portion, the third channel portion has a third volume smaller than the first volume and the second volume;
forming a device layer over the base layer;
forming a semiconductor device vertically over the channel; and
forming a first opening and a second opening through the device layer to connect to the channel, wherein the first opening and the second opening are at laterally opposite sides of the semiconductor device.

17. The method of claim 16, wherein forming the channel comprises:
forming a first trench and a second trench extending downwardly from an upper base surface, the first trench has a narrower width than the second trench; and
forming a cavity under the first trench and the second trench, the cavity is spatially connecting thereto, wherein the portion of the cavity under the first trench extends to a shallower depth from the upper base surface than the portion of the cavity under the second trench.

18. The method of claim 17, further comprises forming a plug in at least the upper portions of the first trench and the second trench.

19. The method of claim 18, wherein forming the plug comprises:
depositing a reflowable material over the upper base surface and conformally lining the surfaces of the channel; and
performing a heat treatment to increase the temperature of the reflowable material to at least the reflow temperature thereof.

20. The method of claim 16, wherein forming the device layer comprises performing an epitaxy process at least over the upper base surface.
